(19) United States
(12) Patent Application Publication
(10) Pub. No.: US 2014/0191301 A1
(43) Pub. Date: Jul. 10, 2014

(54) TRANSISTOR AND FABRICATION METHOD

(71) Applicant: Semiconductor Manufacturing International (Shanghai) Corporation, Shanghai (CN)

(72) Inventors: YOUFENG HE, Shanghai (CN); YONGGEN HE, Shanghai (CN)

(73) Assignee: Semiconductor Manufacturing International (Shanghai) Corporation, Shanghai (CN)

(21) Appl. No.: 14/087,002

(22) Filed: Nov. 22, 2013

(30) Foreign Application Priority Data
Jan. 8, 2013 (CN) 201310006384.3

(51) Int. Cl. H01L 29/78; H01L 29/66

(52) U.S. Cl. CPC H01L 29/7843; H01L 29/665
USPC 257/288; 438/303

(57) ABSTRACT

Transistors and fabrication methods are provided. A first sidewall can be formed on each sidewall of a gate structure. A second sidewall can be formed on the first sidewall. The first sidewall can be made of a doped material. After forming a source and a drain, a metal silicide layer can be formed on the source and the drain. The second sidewall can be removed to expose a surface portion of the semiconductor substrate between the metal silicide layer and the first silicide layer. A stress layer can be formed on the exposed surface portion of the semiconductor substrate, on the metal silicide layer, on the first sidewall, and on the gate.

### CROSS-REFERENCES TO RELATED APPLICATIONS

This application claims the priority to Chinese Patent Application No. CN201310006384.3, filed on Jan. 8, 2013, which is incorporated herein by reference in its entirety.

### FIELD OF THE DISCLOSURE

The present disclosure generally relates to the field of semiconductor technology and, more particularly, relates to a transistor and a method for forming the transistor.

### BACKGROUND

With rapid development of semiconductor manufacturing technology, semiconductor chips are desirable to have high degree of integration such that semiconductor devices may achieve faster computing speed, greater data storage capacity and more features. The higher the degree of integration of the semiconductor chips, the smaller the critical dimension (CD) of the semiconductor devices can be. Currently, as the CD of the semiconductor device shrinks gradually, stress-strain technology (e.g., tress proximity technology, SPT) is used when manufacturing the semiconductor devices.

FIGS. 1-2 show cross-sectional views of a transistor during its formation using conventional tress proximity technology.

Referring to FIG. 1, a substrate 10 is provided and a gate structure is formed on the substrate 10. The gate structure includes a gate dielectric layer 11 on the substrate 10 and a gate 12 on the gate dielectric layer 11.

A lightly doped ion implantation is performed in the substrate 10 on both sides of the gate structure to form a lightly doped source region and a lightly doped drain region (not shown) in the substrate 10.

On both sides of the gate 12, a silicon nitride sidewall spacer 131, a silicon oxide sidewall 132 covering the silicon nitride sidewall spacer 131, and a silicon nitride sidewall 133 covering the silicon oxide sidewall 132 are sequentially formed. The silicon nitride sidewall spacer 131 may define a distance between the source region (and/or the drain region) and the channel region to prevent short channel effect. The silicon nitride sidewall 133 is used to control a distance between a metal silicide layer on the source region (and/or drain region) and the gate. The silicon oxide sidewall 132 may be used as an etch stop layer when subsequently removing the silicon nitride sidewall 133.

A highly doped ion implantation can be performed in the substrate 10 and on both sides of the gate structure to form the source region 141 and the drain region 142. A metal silicide layer 15 may then be formed on the source region 141 and the drain region 142.

Referring to FIG. 2, the silicon nitride sidewall 133 is selectively removed to form a stress layer 16 to cover the gate structure and the silicon oxide sidewall 132. The removal of the silicon nitride sidewall 133 can reduce a distance between the stress layer 16 and the channel region.

As shown in FIGS. 1-2, three layers of sidewall are formed on both sides of the gate structure, which requires complicated manufacturing process and high manufacturing cost. In addition, the silicon oxide sidewall 132 and the silicon nitride sidewall spacer 131 still exist between the stress layer and the gate structure in a resultant semiconductor device. The silicon oxide sidewall 132 reduces stress effect of the stress layer 16 on the channel region.

One solution is to remove the silicon oxide sidewall by an additional etching process. This increases complication of the manufacturing process. Further, the silicon nitride sidewall spacer 131 on both sides of the gate has a high dielectric constant, which causes a high parasitic capacitance surrounding the gate structure of the transistor, adversely affecting device performance.

### BRIEF SUMMARY OF THE DISCLOSURE

One aspect of the present disclosure includes a method of forming a transistor by forming a gate structure on a semiconductor substrate, the gate structure including a gate dielectric layer on the semiconductor substrate and a gate on the gate dielectric layer. A first sidewall can be formed on each sidewall of the gate structure. The first sidewall can be made of a doped material. A second sidewall can be formed on the first sidewall, having an etch rate greater than the first sidewall. A source and a drain can be formed in the semiconductor substrate on both sides of the gate structure. A metal silicide layer can be formed on the semiconductor substrate associated with each of the source and the drain, such that the second sidewall on the semiconductor substrate is between the metal silicide layer and the first silicide layer. After forming the metal silicide layer, the second sidewall can be removed to expose a surface portion of the semiconductor substrate between the metal silicide layer and the first silicide layer. A stress layer can be formed on the surface portion of the semiconductor substrate exposed between the metal silicide layer and the first silicide layer, on the metal silicide layer, on the first sidewall, and on the gate.

Another aspect of the present disclosure includes a transistor. The transistor includes a gate structure disposed on a semiconductor substrate, the gate structure including a gate dielectric layer on the semiconductor substrate and a gate on the gate dielectric layer. A first sidewall can be disposed on each sidewall of the gate structure and can be made of a doped material. A source and a drain can be disposed in the semiconductor substrate on both sides of the gate structure. A metal silicide layer can be disposed on the semiconductor substrate associated with each of the source and the drain and a surface portion of the semiconductor substrate between the metal silicide layer and the first silicide layer is exposed. A stress layer can be disposed on the surface portion of the semiconductor substrate exposed between the metal silicide layer and the first silicide layer, on the metal silicide layer, on the first sidewall, and on the gate.

Other aspects of the present disclosure can be understood by those skilled in the art in light of the description, the claims, and the drawings of the present disclosure.

### BRIEF DESCRIPTION OF THE DRAWINGS

FIGS. 1-2 depict a conventional method for forming a transistor; and

FIGS. 3-9 depict cross-sectional view of an exemplary transistor at various stages during its formation in accordance with various disclosed embodiments.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

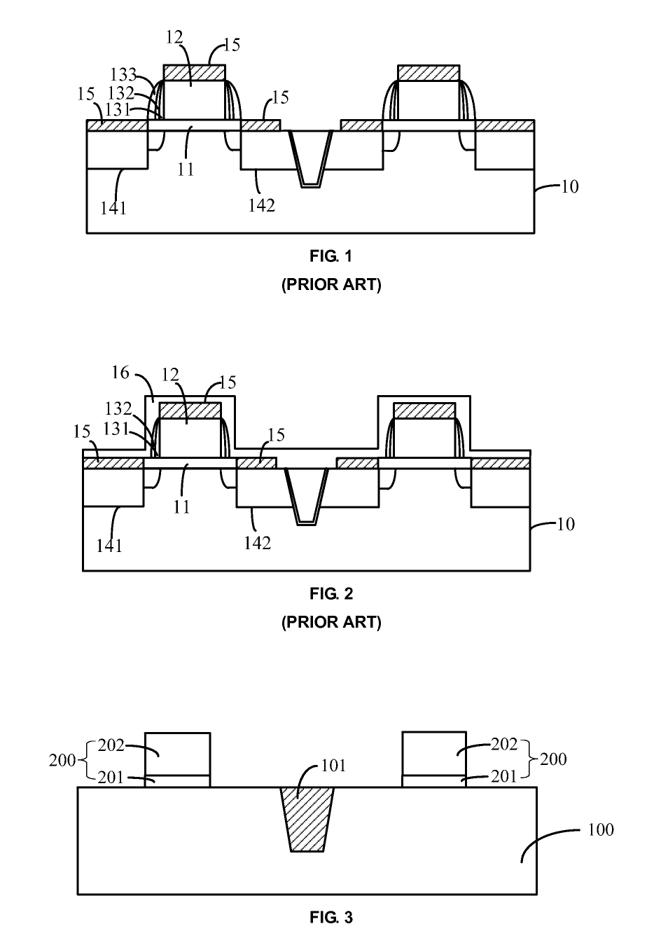

As shown in FIGS. 1-2, three layers of sidewall are formed on both sides of the gate structure, which requires complicated manufacturing process and high manufacturing cost. In addition, because the silicon nitride sidewall spacer on both sides of the gate has a high dielectric constant, a high parasitic capacitance may be caused surrounding the gate structure of the transistor. This may adversely affect device performance.

As disclosed herein, a first sidewall and a second sidewall can be formed on each sidewall of a gate structure. The first sidewall can be made of a doped material, e.g., a doped silicon nitride. A source and a drain can be formed, followed by forming a metal silicide layer on the source and the drain. The second sidewall can be removed. A stress layer can be formed. The removal of the second sidewall layer may reduce a distance between the stress layer and the channel region of the transistor and to improve the stress effect of the stress layer on the formed transistor. In addition, the first sidewall can have a dielectric constant that is sufficiently low such that the parasitic capacitance surrounding the gate structure of the formed transistor can be reduced.

Referring to FIG. 3, a semiconductor substrate 100 is provided. The semiconductor substrate 100 can have an isolation structure 101. A gate structure 200 can be formed on surface of the semiconductor substrate 100 on each side of the isolation structure 101. The gate structure 200 can include a gate dielectric layer 201 on the semiconductor substrate 100 and a gate 202 on the gate dielectric layer 201.

The semiconductor substrate 100 can be formed of a material including, e.g., silicon, germanium, silicon germanium, gallium arsenide, and/or other suitable semiconductor materials. The semiconductor substrate 100 can include a bulk material and/or a composite structure including, e.g., a SOI (silicon on insulator). The semiconductor substrate 100 can be selected depending on the semiconductor device to be formed on the semiconductor substrate 100. In one embodiment, the semiconductor substrate 100 is a silicon substrate.

The isolation structure 101 in the semiconductor substrate 100 can be, e.g., a shallow trench isolation (STI) structure, and/or other suitable isolation structure. The isolation structure 101 can be formed by a method including: forming a trench (not shown) in the semiconductor substrate 100, forming a pad oxide layer (not shown) on inner surface of the trench by a thermal oxidation method, and filling the trench with silicon oxide to form the shallow trench isolation structure.

The gate structure 200 can be formed on the semiconductor substrate 100 on both sides of the isolation structure 101. The gate structure 200 can include the gate dielectric layer 201 on the surface of the semiconductor substrate 100, and the gate 202 on surface of the gate dielectric layer 201.

The gate dielectric layer 201 can be made of a material including, e.g., silicon oxide, silicon oxynitride, a high-k dielectric material, and/or any other suitable dielectric material(s). The gate 202 can be made of a material including, e.g., polysilicon, metal, and/or any other suitable material(s). Exemplary metal can include Ti, Co, Ni, Al, W, and/or any other suitable material(s). In one embodiment, the gate 202 is made of metal.

In other embodiments, one or more additional layers including, e.g., a work function adjusting layer and/or a diffusion barrier layer, can be formed between the gate 202 and the gate dielectric layer 201.

In other embodiments, lightly doped ion implantation can be performed in the semiconductor substrate 100 on both sides of the gate structure to form lightly doped source/drain extension regions.

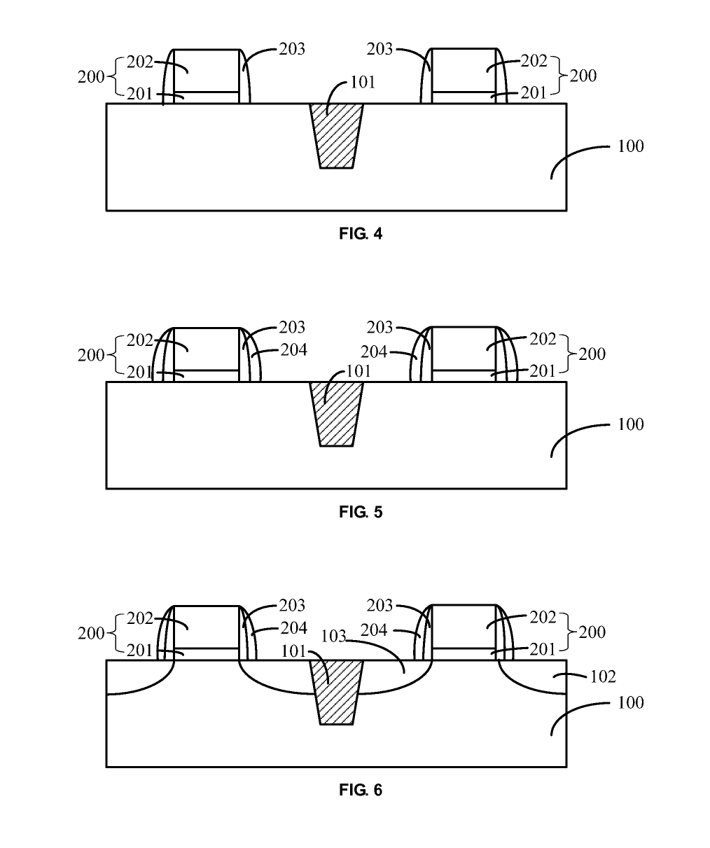

Referring to FIG. 4, a first sidewall 203 is formed on each sidewall of the gate structure 200 to cover the surface of each sidewall of the gate structure 200.

Specifically, the first sidewall 203 can include, e.g., a doped silicon nitride layer. The first sidewall 203 can have a thickness ranging from about 2 nm to about 10 nm. The first sidewall 203 can be doped by a doping element including, e.g., carbon and/or boron. The first sidewall 203 can have a molar concentration of the doping element(s) from about 3% to about 30%. The first sidewall 203 can be formed by a chemical vapor deposition or an atomic layer deposition.

In a certain embodiment, the first sidewall 203 can be a carbon-doped silicon nitride layer. The first sidewall 203 can be formed using a chemical vapor deposition processes including, for example, using a reaction gas containing SiH₂Cl₂, NH3, and C₂H₄, at a reaction temperature ranging from about 450° C. to about 650° C., and having a SiH₂Cl₂ flow rate from about 0.1 standard liter per minute (slm or slpm) to 5 slm, a NH₃ flow rate from about 0.2 slm to about 5 slm, and a C₂H₄ flow rate from about 0.1 to 5 slm. The formed first sidewall 203 can have a carbon concentration ranging from about 1E21 atoms/cm³ to about 5E22 atoms/cm³. Compared with un-doped silicon nitride, the doped silicon nitride layer as the first sidewall 203 can have a sufficiently low etch rate in a phosphoric acid based solution or a hydrofluoric acid based solution. For example, the first sidewall 203 in the phosphoric acid based solution can have an etch rate of less than about 10 nm/min, for example, about 0.1 nm/min to 5 nm/min.

In other embodiments, the first sidewall 203 can include a multilayer-stacked structure. The multilayer-stacked structure can include stacked multiple layers including a silicon nitride layer and a doped silicon nitride layer, and the doped silicon nitride layer can be doped by carbon or boron. The first sidewall 203 can be formed using cyclic deposition processes to sequentially form the silicon nitride layer and the doped silicon nitride layer. Such sequential formation of the silicon nitride layer and the doped silicon nitride layer can be repeatedly performed to form the multilayer-stacked structure. The silicon nitride layer and the doped silicon nitride layer in the first sidewall 203 can have a thickness ratio ranging from about 1:2 to about 1:50.

In another embodiment, the first sidewall 203 can include multilayer-stacked structure including a silicon nitride layer and a carbon-doped silicon nitride layer. The silicon nitride layer in the first sidewall 203 can be formed by an atomic layer deposition including, for example, using SiH₂Cl₂ and NH₃ as reaction gases. The flow rate of SiH₂Cl₂ can be about 0.2 slm to about 5 slm; a NH₃ flow rate can be about 0.5 slm to about 10 slm; a reaction temperature can be about 450° C. to about 650° C.; and a reaction pressure can be about 0.02 Torr to about 1 Torr.

The carbon-doped silicon nitride layer in the first sidewall 203 can be formed by an atomic layer deposition using SiH₂Cl₂, NH₃, and C₂H₄ as reaction gases. The flow rate of SiH₂Cl_{2 can be about} 0.2 slm to about 5 slm; a NH₃ flow rate can be about 0.5 slm to about 10 slm, a C₂H₄ flow rate can be about 0.2 slm to about 5 slm; a reaction temperature can be about 450° C. to about 650° C.; and a reaction pressure can be about 0.02 Torr to about 1 Torr.

In one embodiment, the first sidewall 203 can have a thickness of about 5 nm, and the first sidewall 203 can be formed by first forming a first silicon nitride layer having a thickness of about 1 Å on the semiconductor substrate 100 and on sidewalls and top surface of the gate structure 200. A first carbon-doped silicon nitride layer having a thickness of about 4 Å can then be formed on the silicon nitride layer. A second silicon nitride layer can then be formed on the first carbon-doped silicon nitride layer, followed by a second carbon-doped silicon nitride layer deposited on the second silicon nitride layer. In this manner, a number of cycles, e.g., a total of 10 cycles, of formation of the silicon nitride layer and the carbon-doped silicon nitride layer can be performed. For example, after 10 cycles, a first sidewall material layer can be formed having a thickness of about 5 nm. The first sidewall material layer can then be etched to form the first sidewall 203.

Alternatively, the first carbon-doped silicon nitride layer having a thickness of about 4 Å can be formed first, followed by forming a first silicon nitride layer having a thickness of about 1 Å on the first carbon-doped silicon nitride layer. Such cycle can be repeatedly performed, e.g., to have a total of 10 cycles to form a first sidewall material layer having a thickness of about 5 nm. After etching the first sidewall material layer, a first sidewall 203 can be formed.

Each of the silicon nitride layer and the doped silicon nitride layer in the first sidewall 203 can have a small thickness. When stacked on each other, the doped silicon nitride layers can be considered as uniformly dispersed in the silicon nitride layers. A thickness ratio between the silicon nitride layer and the doped silicon nitride layer in the first sidewall 203 can be controlled and adjusted, by controlling deposition time and/or other deposition conditions of each layer, and/or the number of cycles, such that the doping concentration in the first sidewall 203 can be adjusted, as well as the etch rate and dielectric constant of the first sidewall 203 can further be adjusted.

In some cases, the first sidewall 203 can be formed to include a single layer having a doped silicon nitride layer. The doping concentration can be controlled and/or adjusted by controlling reactant concentration during deposition of the doped silicon nitride layer. In other cases, the first sidewall 203 can include multilayer-stacked structure having a doping concentration that can be controlled and adjusted more conveniently with high accuracy, as compared with a first sidewall having a single layer of the doped silicon nitride layer.

The first sidewall 203 can be subsequently used as an etch stop layer of a silicon nitride layer to be formed. In addition, because the first sidewall 203 is doped with boron, carbon, or other suitable elements, the first sidewall 203 can provide decreased dielectric constant compared with an un-doped silicon nitride layer, and can reduce the parasitic capacitance around the transistor gate structure.

The first sidewall 203 can further define a distance between a source/drain region and the channel region to prevent generation of the short channel effect. In some cases, if the semiconductor substrate 100 on both sides of the gate structure 200 are lightly doped by an ion implantation, prior to forming the first sidewall 203, to form lightly doped source/drain extension regions, the first sidewall 203 can be located on the lightly doped source/drain extension regions. Compared with an un-doped silicon nitride layer, the first sidewall 203 can also block the doped ions (e.g., boron ions) to be diffused outward from the lightly doped source/drain extension regions under the first sidewall 203. This can reduce loss of the doped ions and reduce the resistance of the source/drain regions.

Referring to FIG. 5, a second sidewall 204 can be formed on surface of the first sidewall 203 to cover the first sidewall 203.

Specifically, the second sidewall 204 can have an etch rate sufficiently greater than the etch rate of the first sidewall 203. For example, the second sidewall 204 and the first sidewall 203 can have an etch selectivity ratio of about 4:27. The second sidewall 204 can have a thickness of about 5 nm to about 30 nm. The second sidewall 204 can be formed by a chemical vapor deposition or an atomic layer deposition.

The second sidewall 204 can be made of silicon nitride and formed by a method including, for example, using SiH₂Cl₂ and NH₃ as reaction gases with a flow rate of SiH₂Cl₂ of about 0.2 slm to about 5 slm and a NH₃ flow rate of about 0.5 slm to about 10 slm, at a reaction temperature of about 450° C. to about 650° C. and a reaction pressure of about 0.02 Torr to about 1 Torr.

In other embodiments, the second sidewall 204 can be a silicon nitride layer that is lightly doped with an impurity/doping element having a low content. The doping element can be carbon or boron and can have a doping molar concentration of about 0.5% to about 3%. The lightly doped silicon nitride layer having low impurity content as the second sidewall 204 can have an etch rate greater than the first sidewall 203 in a phosphoric acid solution. In various embodiments, the lightly doped silicon nitride layer having low impurity content as the second sidewall 204 can include a multilayer-stacked structure. Such multilayer-stacked structure can include stacked layers including a silicon nitride layer and a doped silicon nitride layer.

In one embodiment, the second sidewall 204 can include multilayer-stacked structure including a silicon nitride layer and a doped (e.g., carbon-doped) silicon nitride layer. The second sidewall 204 can be formed using cyclic deposition processes to sequentially form the silicon nitride layer and the doped silicon nitride layer. Such sequential formation of the silicon nitride layer and the doped silicon nitride layer can be repeatedly performed to form the multilayer-stacked structure. The silicon nitride layer and the doped silicon nitride layer in the second sidewall 204 can have a thickness ratio ranging from about 1:2 to about 1:50.

For example, the silicon nitride layer in the second sidewall 204 can be formed by an atomic layer deposition including, for example, using SiH₂Cl₂ and NH₃ as reaction gases. A flow rate of SiH₂Cl₂ can be about 0.2 slm to about 5 slm; a NH₃ flow rate can be about 0.5 slm to about 10 slm; a reaction temperature can be about 450° C. to about 650° C.; and a reaction pressure can be about 0.02 Torr to about 1 Torr.

In one embodiment, the second sidewall 204 can have a thickness of about 15 nm, and the second sidewall 204 can be formed by first forming a first silicon nitride layer having a thickness of about 9 Å on the semiconductor substrate 100, on the first sidewall 203, and on the top surface of the gate 202. A first carbon-doped silicon nitride layer having a thickness of about 1 Å can then be formed on the first silicon nitride layer. A second silicon nitride layer can then be formed on the first carbon-doped silicon nitride layer, followed by a second carbon-doped silicon nitride layer deposited on the second silicon nitride layer. In this manner, a number of cycles, e.g., a total of 15 cycles, of formation of the silicon nitride layer and the carbon-doped silicon nitride layer can be performed. For example, after the 15 cycles, a second sidewall material layer can be formed having a thickness of about 15 nm. The second sidewall material layer can then be etched to form the second sidewall 204.

Alternatively, the first carbon-doped silicon nitride layer having a thickness of about 9 Å can be formed first, followed by forming a first silicon nitride layer having a thickness of about 1 Å on the first carbon-doped silicon nitride layer. Such cycle can be repeatedly performed, e.g., to have a total of 15 cycles to form a second sidewall material layer having a thickness of about 15 nm. After etching the second sidewall material layer, a second sidewall 204 can be formed.

A thickness ratio between the silicon nitride layer and the doped silicon nitride layer in the second sidewall 204 can be controlled and adjusted, by controlling deposition time and/or other deposition conditions of each layer, and/or the number of cycles, such that the doping concentration in the second sidewall 204 can be adjusted.

In some cases, the second sidewall 204 can be formed to include a single layer having a doped silicon nitride layer. The doping concentration can be controlled and/or adjusted by controlling reactant concentration during deposition of the doped silicon nitride layer. In other cases, the second sidewall 204 can include a multilayer-stacked structure having a doping concentration that can be controlled and adjusted more conveniently with high accuracy, for example, having a lower doping concentration as compared with a second sidewall having a single layer of the doped silicon nitride layer. The low doping concentration can provide the second sidewall 204 with a high etch rate in the phosphoric acid solution.

In addition, by controlling the thickness ratio between the silicon nitride layer and the doped silicon nitride layer in the second sidewall 204, the second sidewall 204 can be controlled to block the doped ions (e.g., boron ions) to be diffused outward from the lightly doped source/drain extension regions under the second sidewall 204.

The second sidewall 204 can have an etch rate sufficiently greater than the etch rate of the first sidewall 203. For example, the second sidewall 204 and the first sidewall 203 can have an etch selectivity ratio of about 4:27.

When subsequently using a wet etching process to remove the second sidewall 204, the first sidewall 203 can have an etching rate lower than the etch rate of the second sidewall 204. In this manner, when removing the second sidewall 204 subsequently, the first sidewall 203 can be used as an etch stop layer to protect the gate structure 200.

The second sidewall 204 can define a position of subsequently-formed source/drain and can further define a distance, by controlling the thickness of the second sidewall 204, between a metal silicide layer subsequently-formed on a surface of the source/drain region and the gate to prevent current leakage there-between. Compared with an un-doped silicon nitride layer, a doped silicon nitride layer having low impurity content used as the second sidewall 204 can block the doped ions (e.g., boron ions) to be diffused outward from the lightly doped source/drain extension regions. This can reduce loss of the doped ions and reduce the resistance of the source/drain regions.

In other embodiments, the first sidewall 203 and second sidewall 204 can be formed simultaneously. For example, a first sidewall material layer can be formed on surface of the semiconductor substrate 100 and the gate structure 200. A second sidewall material layer can be formed to cover the first sidewall material layer. The first sidewall material layer and a second sidewall material layer can be etched to simultaneously to form the first sidewall 203 and the second sidewall 204.

Referring to FIG. 6, a source 102 and a drain 103 are formed in the semiconductor substrate 100 on both sides of the gate structure 200.

Specifically, in one embodiment, the source 102 and drain 103 can be formed by a method including, for example, using the gate structure 200, the first sidewall 203, and the second sidewall 204 as an mask to perform a p-type or n-type ion implantation into a region in the semiconductor substrate 100 and exposed between the second sidewall 204 and the isolation structure 101. Following the ion implantation process, an annealing process can be performed to form the source 102 and drain 103.

In various embodiments, prior to forming the first sidewall and the second sidewall, a lightly doped ion implantation can be performed in the source/drain region at both sides of the gate structure 200. After formation of the first sidewall 203 and the second sidewall 204, a lightly doped ion implantation can then be performed in the semiconductor substrate 100 exposed by the first sidewall 203 and the second sidewall 204 to form the source and the drain. The lightly doped ion implantation process can reduce hot carrier injection effect and short channel effect of the resultant MOS transistor.

For example, when the semiconductor substrate 100 underlying the first sidewall 203 and second sidewall 204 includes a lightly doped source/drain extension region, the subsequently formed first sidewall 203 and second sidewall 204 can prevent the doped ions in the lightly doped source/drain extension regions from diffusing outward.

In other embodiments, the gate structure 200, the first sidewall 203, and the second sidewall 204 can be used as an etch mask to etch the semiconductor substrate 100 exposed between the second sidewall 204 and the isolation structure 101 to form a groove. The groove can be filled with silicon germanium material and/or silicon carbide material by an epitaxial process to form the source 102 and the drain 103. The silicon germanium material and/or silicon carbide material can be doped with p-type or n-type ions in-situ during the epitaxial process.

In other embodiments, after formation of the silicon germanium material and/or silicon carbide material, an ion implantation process can be performed to dope impurity ions in the silicon germanium material and/or silicon carbide material. Use of the silicon germanium material and/or silicon carbide material to form the source and drain can generate stress exerted on lattices of the channel region of the MOS transistor. This can increase the migration rate of carriers in the channel region to improve the electrical properties of the MOS transistor.

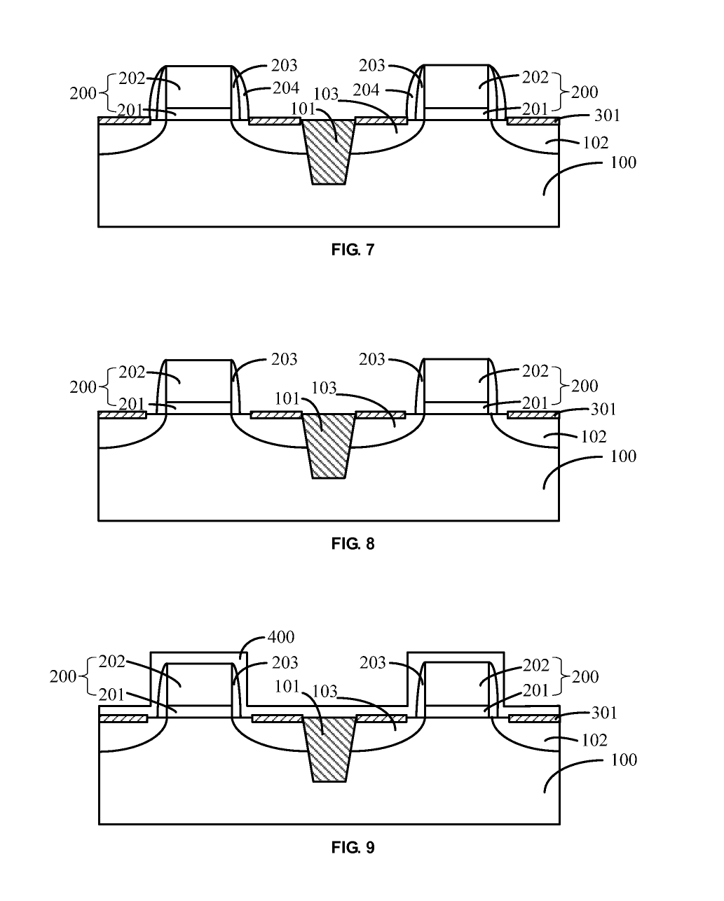

Referring to FIG. 7, a metal silicide layer 301 is formed on surface of the source 102 and the drain 103.

For example, a two-step silicidation process can be used. Firstly, an evaporation or sputtering process can be used to form an exemplary Ni metal layer on surface of each of the source 102, the drain 103, the gate 202, and the isolation structure. In a furnace or rapid thermal annealing apparatus and in a high-purity nitrogen atmosphere, a nickel-rich silicide phase can be formed by a rapid thermal annealing at a low annealing temperature of about 250° C. to about 350° C. (e.g., about 260° C.) for a time duration of about 30 seconds. A wet etching method can be followed to remove excess metal Ni. A high-temperature rapid annealing process can then be performed at an annealing temperature of about 380° C. to about 550° C. (e.g., about 500° C.) for a duration time of about 30 seconds to perform a Ni-rich silicide phase transition to form an exemplary silicide layer 301.

In other embodiments, a one-step silicidation process can be used. For example, an evaporation or sputtering process can be used to form an exemplary Ni metal layer on surface of each of the source 102, the drain 103, the gate 202, and the isolation structure. In a furnace or rapid thermal annealing apparatus and in a high-purity nitrogen atmosphere, a nickel silicide can be formed by a rapid thermal annealing at a high temperature. A wet etching method can then be performed to remove excess Ni to form an exemplary silicide layer 301.

In various embodiments, the metal layer can include, e.g., Ni, Ta, Ti, W, Co, Pt, Pd, or combinations thereof and the formed metal silicide layer 301 can include a material including SiNi, SiTa, SiTi, NiSiPt, and/or other suitable metal silicide material(s). The formation of the metal silicide layer 301 can reduce surface contact resistance of the source 102 and the drain 103.

In one embodiment, the gate can be made of a material including a metal.

In this case, no metal silicide layer can be formed on surface of the gate 202. In other embodiments, if the gate 202 is made of a material of polysilicon, a metal silicide layer can be formed on the polysilicon gate.

Refer to FIG. 8, the second sidewall 204 is removed. In one embodiment, a wet etching process can be used to remove the second sidewall 204. The wet etching process can use an etching solution including a phosphoric acid solution. The phosphoric acid solution can have a temperature ranging from about 120° C. to about 165° C. for an etching time of about 1 minute to about 65 minutes.

Table 1 shows etch rates of a first sidewall 203 using a doped silicon nitride layer and a second sidewall 204 using a silicon nitride layer, and a conventional silicon oxide layer, in a 49% hydrofluoric (HF) acid and in a phosphoric acid solution.

TABLE 1
Etch Rate Table

| | 300:1 Diluted HF | Phosphoric acid |
|---|---|---|
| Layer type | Solution | solution |
| doped silicon nitride layer | 0.099 nm/min | 0.2 nm/min |
| silicon nitride layer | 0.38 nm/min | 5.4 nm/min |
| silicon oxide layer | 2.9 nm/min | 0.15 nm/min |

As indicated by Table 1, the first sidewall 203 can have an etch rate of about 0.2 nm/min in the phosphoric acid solution, while the second sidewall 204 formed of the silicon nitride layer can have an etch rate of about 5.4 nm/min in the phosphoric acid solution. Compared with the first sidewall 203, the second sidewall 204 can have a greater ratio of etch selectivity. The first sidewall 203 can therefore be used as an etch stop layer to protect the gate structure 200 when etching to remove the second sidewall 204.

After removal of the second sidewall 204, the first sidewall 203 can remain on sidewall surface of the gate structure 200. The first sidewall 203 can be a doped silicon nitride layer having a single layer structure or a multilayer-stacked structure including a non-doped silicon nitride layer and a doped silicon nitride layer stacked together. Because the silicon nitride layer is doped with elements including carbon or boron, which can reduce dielectric constant of the first sidewall 203. Parasitic capacitance at periphery of the gate structure of the formed transistor can be reduced.

Referring to FIG. 9, a stress layer 400 is formed on surface of the semiconductor substrate 100. The stress layer 400 covers entire surface of the structure shown in FIG. 8 including, each surface of the semiconductor substrate 100, the source 102, the drain 103, the metal silicide layer 301, the gate 202, and/or the first sidewall 203.

The stress layer 400 can be formed by a thermal chemical vapor deposition or plasma enhanced chemical vapor deposition. When the transistor to be formed is an NMOS transistor, the stress layer 400 has a stress type of tensile stress to provide the channel region of the NMOS transistor with tensile stress and to improve electron mobility in the channel region of the NMOS transistor and to improve device performance of the NMOS transistor. When the transistor to be formed is a PMOS transistor, the stress layer 400 has a stress type of compressive stress to provide the channel region of the PMOS transistor with compressive stress and to improve hole mobility in the channel region of the PMOS transistor and to improve device performance of the PMOS transistor.

When forming a CMOS transistor, a stress layer with high tensile stress can be deposited to improve NMOS performance in the CMOS transistor. A reactive ion etching method can then be used to remove the stress layer from the top of the PMOS. A compressive stress layer can then be deposited on the PMOS transistor. In this manner, the CMOS of the NMOS transistor can include a tensile stress layer and the PMOS of the NMOS transistor can include a compressive stress layer such that device performance of the PMOS and NMOS can be improved.

Prior to forming the stress layer 400, the second sidewall 204 (referring to FIG. 7) can be removed to reduce a distance between the stress layer 400 and the channel region of the transistor, thereby improving the stress effect of the stress layer 400 on the transistor and further improving transistor performance.

Subsequently, an interlayer dielectric layer (not shown) can be formed on surface of the stress layer 400. A through hole can be formed in the interlayer dielectric layer by an etching process. The stress layer can be used as an etch barrier layer when etching the dielectric layer.

Still referring to FIG. 9, the disclosed transistor includes a semiconductor substrate 100; a gate structure 200 located on the semiconductor substrate 100, the gate structure 200 including a gate dielectric layer 201 on surface of the semiconductor substrate 100, and a gate 202 on surface of the gate dielectric layer 201; a first sidewall 203 on each sidewall of the gate structure 200; a source 102 and a drain 103 located in the semiconductor substrate 100 on both sides of the gate structure 200; a metal silicide layer 301 on surface of the source 102 and the drain 103; and//or a stress layer 400 on surface of the semiconductor substrate 100 to cover each surface of the source 102, the drain 103, the metal silicide layer 301, the gate 202, and the first sidewall 203 of the transistor.

In one embodiment, the first sidewall 203 is made of a doped silicon nitride layer. The first sidewall 203 has a thickness of about 2 nm to about 10 nm. The first sidewall 203 is doped with a doping element including carbon and/or boron and having a molar concentration of about 3% to about 30%.

The first sidewall 203 is made of a carbon-doped silicon nitride layer. The first sidewall 203 has a carbon concentration of about 1E21 carbon atoms/cm³ to about 5E22 carbon atoms/cm³. Compared with un-doped silicon nitride layer, the first sidewall 203 has a low etch rate in a phosphoric acid solution or a hydrofluoric acid solution. The first sidewall 203 has an etch rate of less than about 10 nm/min.

In other embodiments, the first sidewall 203 includes a multilayer-stacked structure including an un-doped silicon nitride layer and a doped silicon nitride layer stacked together. The doped silicon nitride layer is doped by a doping element including carbon or boron. The un-doped silicon nitride layer and the doped silicon nitride layer in the first sidewall 203 have a thickness ratio of about 1:2 to about 1:50 with a doping molar concentration of about 3% to about 30%. In one embodiment, the first sidewall 203 includes multilayer-stacked structure including a carbon-doped silicon nitride layer and an un-doped silicon nitride layer.

Each of the un-doped silicon nitride layer and the doped silicon nitride layer in the first sidewall 203 can have a small thickness. When stacked on each other, the doped silicon nitride layers can be considered as uniformly dispersed in the silicon nitride layers. A thickness ratio between the silicon nitride layer and the doped silicon nitride layer in the first sidewall 203 can be controlled and adjusted, by controlling deposition time and/or other deposition conditions of each layer, and/or the number of cycles, such that the doping concentration in the first sidewall 203 can be adjusted and the etch rate and dielectric constant of the first sidewall 203 can further be adjusted.

In some cases, the first sidewall 203 can be formed to include a single layer having a doped silicon nitride layer. The doping concentration can be controlled and/or adjusted by controlling reactant concentration during deposition of the doped silicon nitride layer. In other cases, the first sidewall 203 can include multilayer-stacked structure having a doping concentration that can be controlled and adjusted more conveniently with high accuracy, as compared with a first sidewall having a single layer of the doped silicon nitride layer.

The first sidewall 203 can be subsequently used as an etch stop layer of a silicon nitride layer to be formed. In addition, because the first sidewall 203 is doped with boron, carbon, or other suitable elements, the first sidewall 203 can provide decreased dielectric constant compared with an un-doped silicon nitride layer, and can reduce the parasitic capacitance around to the transistor gate structure.

In some cases, if the semiconductor substrate 100 on both sides of the gate structure 200 are lightly doped by an ion implantation, prior to forming the first sidewall 203, to form lightly doped source/drain extension regions, the first sidewall 203 can be located over the lightly doped source/drain extension regions. Compared with un-doped silicon nitride layer, the first sidewall 203 can also block the doped ions (e.g., boron ions) to be diffused outward from the lightly doped source/drain extension regions below the first sidewall 203. This can reduce loss of the doped ions and reduce the resistance of the source/drain regions.

When the transistor to be formed is an NMOS transistor, the stress layer 400 has a stress type of tensile stress to provide the channel region of the NMOS transistor with tensile stress and to improve electron mobility in the channel region of the NMOS transistor and to improve device performance of the NMOS transistor. When the transistor to be formed is a PMOS transistor, the stress layer 400 has a stress type of compressive stress to provide the channel region of the PMOS transistor with compressive stress and to improve hole mobility in the channel region of the PMOS transistor and to improve device performance of the PMOS transistor.

When forming a CMOS transistor, a stress layer with high tensile stress can be deposited to improve NMOS performance in the CMOS transistor. A reactive ion etching method can then be used to remove the stress layer from the top of the PMOS. A compressive stress layer can be deposited on the PMOS transistor. In this manner, the CMOS of the NMOS transistor can include a tensile stress layer and the PMOS of the NMOS transistor can include a compressive stress layer such that device performance of the PMOS and NMOS can be improved.

Because only the first sidewall 203 is disposed between the stress layer 400 and the transistor gate structure 200, compared with conventional multiple sidewalls, a distance between the stress layer 400 and the channel region is decreased. The stress effect of the stress layer 400 on the transistor is improved and transistor performance further improved.

Other applications, advantages, alternations, modifications, or equivalents to the disclosed embodiments are obvious to those skilled in the art.

What is claimed is:

1. A method of forming a transistor, comprising:
forming a gate structure on a semiconductor substrate, the gate structure including a gate dielectric layer on the semiconductor substrate and a gate on the gate dielectric layer;
forming a first sidewall on each sidewall of the gate structure, wherein the first sidewall is made of a doped material;
forming a second sidewall on the first sidewall, wherein the second sidewall is formed of a material having an etch rate greater than the first sidewall;
forming a source and a drain in the semiconductor substrate on both sides of the gate structure;
forming a metal silicide layer on the semiconductor substrate associated with each of the source and the drain, such that the second sidewall on the semiconductor substrate is between the metal silicide layer and the first silicide layer;
after forming the metal silicide layer, removing the second sidewall to expose a surface portion of the semiconductor substrate between the metal silicide layer and the first silicide layer; and
forming a stress layer on the surface portion of the semiconductor substrate exposed between the metal silicide layer and the first silicide layer, on the metal silicide layer, on the first sidewall, and on the gate.

2. The method of claim 1, wherein the first sidewall includes a doping element including carbon or boron, and has a molar concentration of the doping element of about 3% to about 30%.

3. The method of claim 1, wherein the second sidewall and the first sidewall has an etch selectivity ratio of about 4:1 to about 27:1.

4. The method of claim 1, wherein the first sidewall has a thickness ranging from about 2 nm to about 10 nm and an etch rate of less than about 5 nm/min in a phosphoric acid solution.

5. The method of claim 1, wherein forming the first sidewall or the second sidewall includes a chemical vapor deposition or an atomic layer deposition.

6. The method of claim 1, wherein forming the first sidewall includes using a reaction gas containing SiH₂Cl₂, NH₃, and C₂H₄ at a reaction temperature ranging from about 450° C. to about 650° C., wherein a SiH₂Cl₂ flow rate ranges from about 0.1 slm to about 5 slm, a NH₃ flow rate ranges from about 0.2 slm to about 5 slm, and a C₂H₄ flow rate ranges from about 0.1 to 5 slm, and wherein the first sidewall has a carbon concentration ranging from about 1E21 atoms/cm³ to about 5E22 atoms/cm³.

7. The method of claim 1, wherein the first sidewall includes a multilayer-stacked structure, the multilayer-stacked structure including an un-doped silicon nitride layer and a doped silicon nitride layer stacked together, and wherein the un-doped silicon nitride layer and the doped silicon nitride layer in the first sidewall have a thickness ratio ranging from about 1:2 and 1:50.

8. The method of claim 7, wherein the undoped silicon nitride layer in the first sidewall is formed by an atomic layer deposition using a reaction gas containing SiH₂Cl₂ and NH₃ at a reaction temperature ranging from about 450° C. to about 650° C. and a reaction pressure ranging from about 0.02 Torr to about 1 Torr, and wherein a SiH₂Cl₂ flow rate is about 0.2 slm to about 5 slm and a NH₃ flow rate is about 0.5 slm to about 10 slm; and wherein the doped silicon nitride layer in the first sidewall is formed by an atomic layer deposition using a reaction gas containing SiH₂Cl₂, NH₃, and C₂H₄ at a reaction temperature ranging from about 450° C. to about 650° C. and a reaction pressure ranging from about 0.02 Torr to about 1 Torr, wherein a SiH₂Cl₂ flow rate is about 0.2 slm to about 5 slm, a NH₃ flow rate is about 0.5 slm to about 10 slm, and a C₂H₄ flow rate is about 0.2 slm to about 5 slm.

9. The method of claim 1, wherein the second sidewall is a silicon nitride layer.

10. The method of claim 1, wherein the second sidewall includes a multilayer-stacked structure, the multilayer-stacked structure including an un-doped silicon nitride layer and a doped silicon nitride layer stacked together, and wherein the un-doped silicon nitride layer and the doped silicon nitride layer in the second sidewall has a thickness ratio ranging from about 2:1 and 50:1.

11. The method of claim 10, wherein the doped silicon nitride layer in the second sidewall is doped by a doping element including carbon or boron, and has a molar concentration of the doping element ranging from about 0.5% to about 3%.

12. The method of claim 10, wherein the multilayer-stacked structure of the second sidewall is formed by a cyclic deposition process.

13. The method of claim 1, wherein removing the second sidewall includes using a phosphoric acid solution as an etching solution at an etching temperature ranging from about 120° C. to about 165° C. for an etching time ranging from about 1 minute to about 65 minutes.

14. The method of claim 1, wherein the second sidewall is removed to provide a reduced distance between the stress layer formed on the exposed surface region of the semiconductor substrate and a channel region in the semiconductor substrate under the gate structure.

15. A transistor comprising:
a gate structure disposed on a semiconductor substrate, the gate structure including a gate dielectric layer on the semiconductor substrate and a gate on the gate dielectric layer;
a first sidewall disposed on each sidewall of the gate structure, wherein the first sidewall is made of a doped material;
a source and a drain in the semiconductor substrate on both sides of the gate structure;
a metal silicide layer disposed on the semiconductor substrate associated with each of the source and the drain, wherein a surface portion of the semiconductor substrate between the metal silicide layer and the first silicide layer is exposed; and
a stress layer disposed on the surface portion of the semiconductor substrate exposed between the metal silicide layer and the first silicide layer, on the metal silicide layer, on the first sidewall, and on the gate.

16. The transistor of claim 15, wherein the first sidewall includes a doping element including carbon or boron, and has a molar concentration of the doping element of about 3% to about 30% to provide a reduced dielectric constant.

17. The transistor of claim 15, wherein the first sidewall has a carbon concentration ranging from about 1E21 atoms/cm³ to about 5E22 atoms/cm³.

18. The transistor of claim 15, wherein the first sidewall has a thickness ranging from about 2 nm to about 10 nm.

19. The transistor of claim 15, wherein the first sidewall has an etch rate of less than about 5 nm/min in a phosphoric acid solution.

20. The transistor of claim 15, wherein the first sidewall includes a multilayer-stacked structure, the multilayer-stacked structure including an un-doped silicon nitride layer and a doped silicon nitride layer stacked together, and wherein the un-doped silicon nitride layer and the doped silicon nitride layer in the first sidewall has a thickness ratio ranging from about 1:2 and 1:50.
